(19) United States
(12) Patent Application Publication
(10) Pub. No.: US 2026/0191093 A1
(43) Pub. Date: Jul. 2, 2026

(54) MOLDED CHIP PACKAGING AND PROCESS FOR MAKING THE SAME

(71) Applicant: Intel Corporation, Santa Clara, CA (US)

(72) Inventors: Aruna MANOHARAN, Gilbert, AZ (US); Richard PATTEN, Langquaid (DE)

(21) Appl. No.: 19/002,873

(22) Filed: Dec. 27, 2024

(51) Int. Cl. H01L 23/18; H01L 21/56; H01L 23/00; H01L 23/31; H01L 25/065

(52) U.S. Cl. CPC H10W 76/42; H10W 74/016; H10W 74/114; H10W 74/10; H10W 90/00; H10W 90/724

(57) ABSTRACT

A semiconductor device is provided. The semiconductor device includes: a substrate; at least one chip die coupled to a top surface of the substrate at a central portion of the substrate; a reinforcement structure disposed around the at least one chip die, a bottom surface of the reinforcement structure coupled to the top surface of the substrate; and a mold structure surrounding the reinforcement structure and at least one chip die.

### TECHNICAL FIELD

The present disclosure generally relates to semiconductor packaging and a process for making the same, in particular, a molded chip packaging and a process thereof.

### BACKGROUND

In contemporary molded chip packaging, improving manufacturing efficiency and providing reliability and heat dissipation introduces significant technical challenges and cost implications.

Therefore, there exists a need to provide an improved molded chip packaging and a process for making the same.

### BRIEF DESCRIPTION OF THE DRAWINGS

The accompanying drawings serve to provide an understanding of non-limiting aspects. Further non-limiting aspects and many of the intended advantages will become apparent directly from the following detailed description. The elements and structures shown in the drawings are not necessarily shown to scale relative to each other. Like reference numerals refer to like or corresponding elements and structures. Non-limiting aspects of the present disclosure will be better understood by one of ordinary skill in the art from the following detailed description and in conjunction with the drawings, in which:

FIGS. 1A and 1B are diagrams showing a cross-sectional view (with mold) and a top view (without mold) of a large body FCCSP 100 according to various non-limiting aspects of the present disclosure.

FIGS. 2A and 2B are diagrams showing a cross-sectional view (with mold) and a top view (without mold) of a large body FCCSP 200 according to various non-limiting aspects of the present disclosure.

FIGS. 3A and 3B are diagrams showing a cross-sectional view (with mold) and a top view (without mold) of a large body FCCSP 300 according to various non-limiting aspects of the present disclosure.

FIGS. 4A and 4B are diagrams showing a cross-sectional view (with mold) and a top view (without mold) of a large body FCCSP 400 according to various non-limiting aspects of the present disclosure.

FIGS. 5A and 5B are diagrams showing a cross-sectional view (with mold) and a top view (without mold) of a large body FCCSP 500 according to various non-limiting aspects of the present disclosure.

FIGS. 6A and 6B are diagrams showing a cross-sectional view (with mold) and a top view (without mold) of a large body FCCSP 600 according to various non-limiting aspects of the present disclosure.

FIGS. 7A and 7B are diagrams showing a cross-sectional view (with mold) and a top view (without mold) of a large body FCCSP 700 according to various non-limiting aspects of the present disclosure.

FIG. 8 illustrates a block diagram of the standard FCCSSP assembly process flow including the reinforcement or stiffener structure addition.

FIGS. 9A and 9B are diagrams showing a top view and a cross-sectional view of a chip module 900 prior to attachment of a reinforcement structure according to various non-limiting aspects of the present disclosure.

FIGS. 10A and 10B are diagrams showing a top view and a cross-sectional view of a chip module 900 after attachment of a reinforcement structure according to various non-limiting aspects of the present disclosure.

FIGS. 11A and 11B are diagrams showing a top view and a cross-sectional view of a chip module 900 after encapsulating a reinforcement structure in a mold according to various non-limiting aspects of the present disclosure.

FIGS. 12A and 12B are diagrams showing a top view and a cross-sectional view of a chip module 900 after encapsulating a reinforcement structure in a mold according to various non-limiting aspects of the present disclosure.

FIG. 13 illustrates a block diagram of the standard FCCSP assembly process flow including the reinforcement addition.

FIG. 14 illustrates a block diagram of the standard FCBGA assembly process flow including the reinforcement addition.

FIGS. 15A and 15B are diagrams showing a top view (without mold) and a cross-sectional view (with mold) of a chip module 1500 according to various non-limiting aspects of the present disclosure.

### DETAILED DESCRIPTION

Aspects described below in the context of a method are analogously valid for the respective element, device, apparatus, or system, and vice versa. Furthermore, it will be understood that the aspects described below may be combined, for example, a part of one aspect may be combined with a part of another aspect, and a part of one aspect may be combined with a part of another aspect.

It should be understood that the singular terms “a”, “an”, and “the” include plural references unless context clearly indicates otherwise. Similarly, the word “or” is intended to include “and” unless the context clearly indicates otherwise.

It will be further understood that the terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Approximating language, as used herein throughout the specification and claims, may be applied to modify any quantitative representation that could permissibly vary without resulting in a change in the basic function to which it is related. Accordingly, a value modified by a term or terms, such as “about,” “substantially”, is not limited to the precise value specified but within tolerances that are acceptable for operation of the aspect for an application for which it is intended. In some instances, the approximating language may correspond to the precision of an instrument for measuring the value.

The term “exemplary” may be used herein to mean “serving as an example, instance, or illustration”. Any aspect or design described herein as “exemplary” is not necessarily to be construed as preferred or advantageous over other aspects or designs.

The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The term “first”, “second”, “third” detailed herein are used to distinguish one element from another similar element and may not necessarily denote order or relative importance, unless otherwise stated. For example, a first transaction data, a second transaction data may be used to distinguish two transactions based on two different foreign currency exchange.

As used herein, the term “connect/connected/connection” may refer to a wired or wireless communication link formed between electronic devices that enables data transmission.

Contemporary flip chip packaging is a process for interconnecting dies such as semiconductor devices, integrated circuit (IC) chips, integrated passive devices and microelectromechanical systems (MEMS), to external circuitry. Dies are created on the wafer. Metal pads are formed on the top surface of the dies. A solder ball/bump is deposited on each of the pads. In order to mount the die to external circuitry (e.g., a circuit board or another chip or wafer), it is flipped over so that its top side faces down, and aligned so that its pads align with matching pads on the external circuit, and then the solder is reflowed to complete the interconnect. The mounted die is underfilled using a (capillary, shown here) electrically-insulating adhesive. The mounted die is then encapsulated in a mold.

Various non-limiting aspects described herein seek to provide an advantageous and efficient packaged chip module.

### Large Body FCCSP (Flip Chip Chip Scale Package) with Stiffener

FCCSP package sizes are currently limited to chip modules with a 20 mm×20 mm body size. The present disclosure describes a stiffener element to facilitate the application of FCCSP to chip modules having larger body sizes, i.e., a body size over 20 mm×20 mm. The addition of a stiffener element and attachment process allows the FCCSP technology platform to have the capability to package chip modules having larger body sizes.

Large body FCCSP provides cost savings by transitioning from a small form factor FCBGA (Flip Chip Ball Grid Array) platform into the more cost effective and efficient FCCSP platform.

Previously, chip modules with large body sizes were only accommodated by the FCBGA technology platform. The FCBGA technology platform is characterized by a singulated unit package that is unmolded and includes large keep out zones.

The FCCSP platform currently requires a body size that is less than 20 mm×20 mm. Adding a stiffener to address warpage problems facilitates large body FCCSP packaging. This solution provides the FCCSP technology platform the capability to produce large body FCCSP. That is, a body size greater than 20 mm×20 mm may be realized with FCCSP packaging by adding a stiffener into the FCCSP platform.

The present disclosure provides cost savings by transitioning from small form factor FCBGA into large body FCCSP.

The present disclosure provides extending the FCCSP technology platform to body sizes over 20 mm×20 mm. By reducing package warpage, crossover FCBGA products may be packaged with FCCSP technology instead.

FCCSP processing has lower throughput time (TPT) and offers cost savings by utilizing substrates in strip form. A FCCSP strip for a 23 mm×23 mm body size can accommodate 24 units per strip/196 units per panel. Whereas each 23 mm×23 mm body size in FCBGA processing is processed as a single unit.

FCCSP processing offers opportunities with more options in material set. FCCSP processing also provides utilization of thin cores to improve Current Carrying Density where FCBGA does not support thin cores.

The present disclosure provides adding a reinforcement or stiffener structure to a FCCSP package to support large body FCCSP and extend the FCCSP platform capability beyond 20 mm×20 mm package size. The reinforcement or stiffener structure may be a rigid structure that is added as an attachment on the top surface of the substrate. The stiffener is sized according to the die size. The material, thickness and foot width of the reinforcer or stiffener is determined by the warpage on the particular product package.

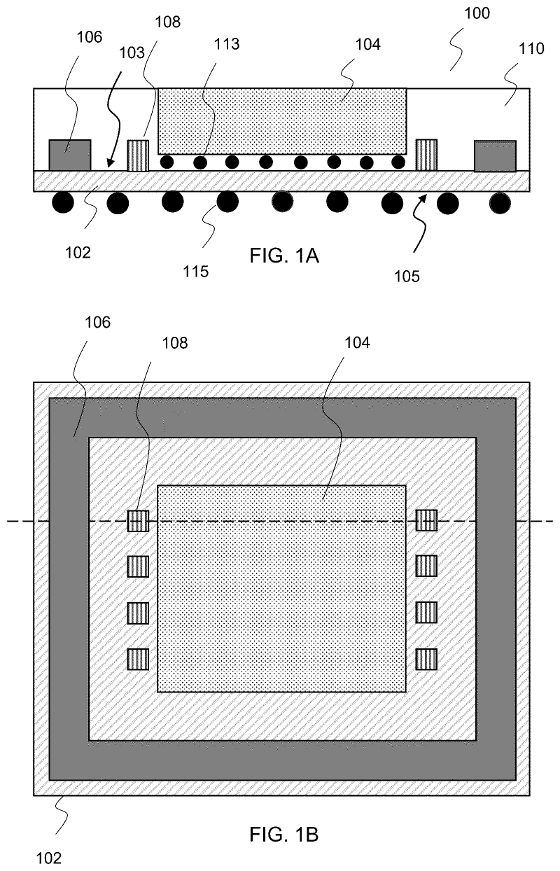

FIGS. 1A and 1B are diagrams showing a cross-sectional view (with mold) and a top view (without mold) of a large body FCCSP 100 according to various non-limiting aspects of the present disclosure. Referring to FIG. 1A, a flip chip die 104 is mounted on a substrate 102 and a stiffener element (or reinforcement structure) 106 is coupled (e.g., attached) to the substrate. Referring to FIG. 1B, the stiffener element (or reinforcement structure) 106 is arranged around the flip chip die. The stiffener element 106 reinforces the substrate and provides additional stability to the substrate to prevent warpage. The stiffener element 106 and flip chip die 104 are encapsulated by a mold 110.

By adding the stiffener (or reinforcement) element 106, the substrate size for FCCSP may be larger than 20 mm×20 mm. The substrate 102 may have a top surface 103 and a bottom surface 105. The top surface 103 may include solder bumps 113 configured to connect to a flip chip die 104 and the bottom surface 105 may include solder balls 115. The solder balls 115 may be configured to connect to a printed circuit board. The substrate 102 may include one or more routing layers connecting the solder bumps 113 to the solder balls 115.

The flip chip die 104 may be a semiconductor device, an IC device, a passive device, or a MEMs device. The flip chip die 104 may be mounted on the top surface 103 of a substrate 102 by solder bumps 113. In some non-limiting embodiments, the flip chip die 104 may be centered with respect to the substrate 102. In some non-limiting embodiments, the flip chip die 104 may be one of a plurality of flip chip dies.

The stiffener element 106 is made of a rigid material. The stiffener element 106 reinforces and stabilizes the substrate to eliminate or minimize warpage of the substrate. For example, in some non-limiting embodiments, the stiffener element 106 may be made of metal or metal alloys, e.g., stainless steel, copper, silver, gold, aluminum, nickel, chromium, etc. and alloys thereof. In some non-limiting embodiments, the stiffener element 106 may be made of plastic, ceramic, or polymer structure.

The stiffener element 106 may be one or more prefabricated pieces coupled (e.g., adhered) to the top surface 103 of the substrate 102. An adhesive such an epoxy-based or silicone-based adhesive may be used to couple (e.g., attach) the stiffener element 106 to the substrate. The stiffener element 106 may be directly coupled (e.g., attached) to the substrate 102 using an adhesive.

In some non-limiting embodiments, passive components 108 may be coupled (e.g., attached) to the top surface 103 of the substrate 102. The passive components 108 may be coupled (e.g., attached) by solder. For example, capacitors may be added depending on the product and packaging requirements.

The flip chip die 104, stiffener element 106 and any passive component 108 is encapsulated in a mold 110. The mold 110 may be a gallium based polymer. The mold may be any material commonly used in standard FCCSP processing.

The stiffener element 106 may have various shapes and configurations. The stiffener element 106 should be smaller in dimension that the substrate so that it does not extend beyond the substrate.

In some non-limiting embodiments, the stiffener element 106 may be a ring or frame arranged around a flip chip die 104. In some non-limiting embodiments, the stiffener element 106 may be a ring or frame arranged around a plurality of flip chip dies 104. In a non-limiting embodiment, the ring or frame may be continuous. In a non-limiting embodiment, the ring or frame may be symmetrically arranged with respect to the flip chip die 104 or the plurality of flip chip dies 104. In a non-limiting embodiment, the ring or frame may have a perimeter about the same size as the perimeter of the flip chip die 104 or the perimeter of the plurality of flip chip dies (e.g., arranged along the collective outer perimeter of the group of flip chip dies). In a non-limiting embodiment, the ring or frame may have a perimeter about the same size as the perimeter of the substrate 102 (e.g., arranged along the edges of the substrate).

In some non-limiting embodiments, the stiffener element 106 may be a plurality of nested rings or frames arranged around the flip chip die 104 or the plurality of flip chip dies 104. For example, a first ring or frame 106a may surround the flip chip die 104 (or plurality of flip chip dies) and a second ring or frame 106b may surround the first ring or frame 106a and the flip chip die 104 (or plurality of flip chip dies).

In some non-limiting embodiments, the stiffener element 106 may partially surround the flip chip die 104 or the plurality of flip chip dies 104. In a non-limiting embodiment, the stiffener element may be two stabilizing bars 126 positioned on opposing sides of the flip chip die 104 or the plurality of flip chip dies 104. In a non-limiting embodiment, the stiffener element 106 may be a plurality of L-shaped brackets 136 arranged at two or more corners of the flip chip die 104. In a non-limiting embodiment, the stiffener element 106 may be a plurality of L-shaped brackets 136 arranged at two or more outer corners of the plurality of flip chip dies 104 (e.g., arranged at corners corresponding to the collective outer perimeter of the group of flip chip dies).

The cross-sectional shape of the stiffener element 106 may be any shape with a planar (e.g. flat) bottom, e.g., square, rectangular, trapezoidal or triangular. The planar or flat bottom portions facilitates proper adhesion between the stiffener element 106 and the substrate 102. The planar or flat bottom portion of the stiffener element 106 is coupled (e.g., adhered) to the substrate 102. An adhesive may be used. For example, the planar portions continuously contact the substrate via the adhesive.

The cross-sectional height and width of the stiffener element 106 is sized to provide sufficient rigidity to prevent warpage. The height may extend upto the height of the flip chip die. The width of the stiffener element 106 may extend up to the distance between the flip chip die edge and the substrate edge.

The large body FCCSP 100 may include optional passive components 108 (e.g. capacitors) arranged on the top surface 103 of the substrate 102. In some non-limiting embodiments, the passive components 108 may be arranged between the flip chip die 104 and the stiffener element 106. In some non-limiting embodiments, the passive components 108 may be arranged between the stiffener element 106 and a perimeter of the substrate.

FIG. 1B shows a large body FCCSP 100 where the stiffener element 106 is a frame (e.g., rectangular or other shape) arranged around the flip chip die 104. The frame is arranged around the perimeter of the substrate 102. Passive components 108 (e.g. capacitors, inductors, resistors) may be arranged on the substrate 102 between the flip chip 104 and the stiffener element 106.

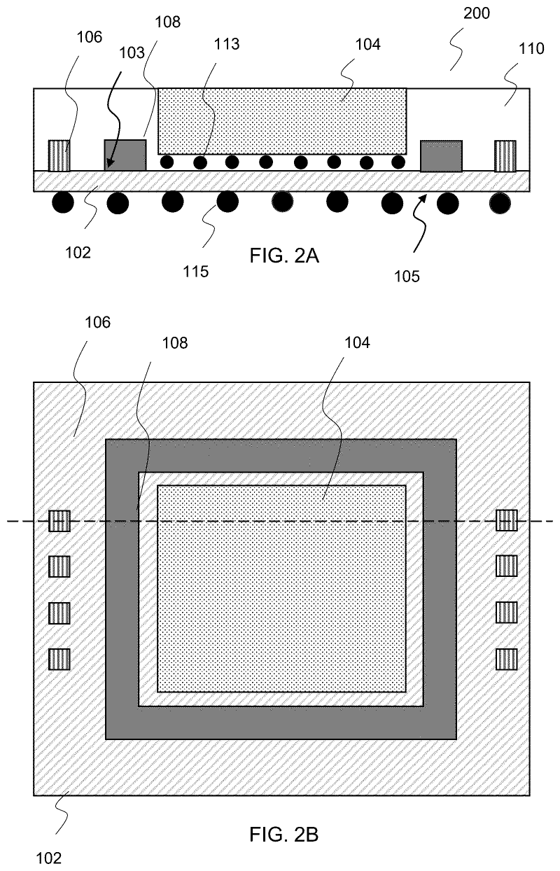

FIGS. 2A and 2B are diagrams showing a cross-sectional view (with mold) and a top view (without mold) of a large body FCCSP 200 according to various non-limiting aspects of the present disclosure. FIGS. 2A and 2B show a large body FCCSP 200 where the stiffener element 106 is a frame (e.g., rectangular or other shape) arranged around the flip chip die 104 approximately along a perimeter of the flip chip die 104. Passive components 108 (e.g. capacitors, inductors, resistors) may be arranged on the substrate 102 between the stiffener element 106 and the edges of the substrate 102.

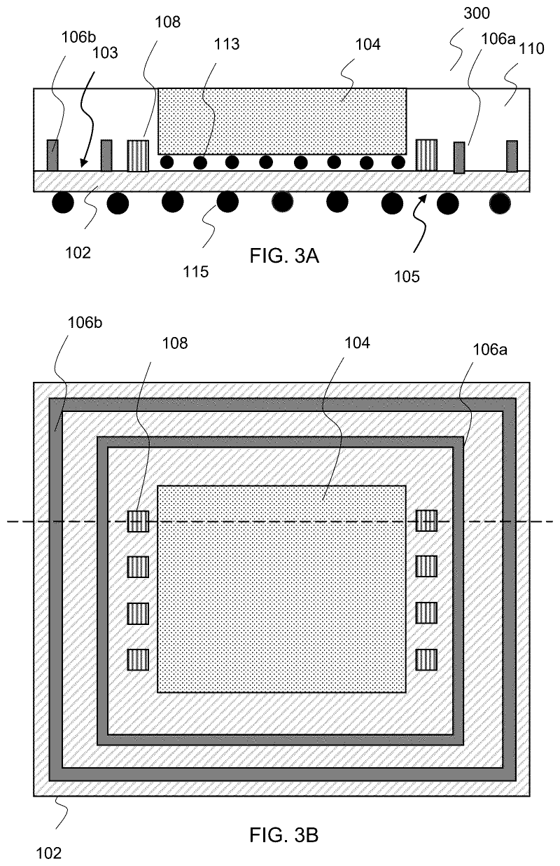

FIGS. 3A and 3B are diagrams showing a cross-sectional view (with mold) and a top view (without mold) of a large body FCCSP 300 according to various non-limiting aspects of the present disclosure. FIGS. 3A and 3B show a large body FCCSP 300 where the stiffener element 106 includes two nested frames 106a and 106b (e.g., rectangular, circular or other shape) coupled (e.g., attached) to the substrate 102. A first frame 106a is arranged around the flip chip die 104. A second frame 106b is arranged around the flip chip die 104 and the first frame 106a. Passive components 108 (e.g. capacitors, inductors, resistors) may be arranged on the substrate 102. For example, the passive components 108 may be coupled (e.g., attached) to the substrate 102 within the first frame 106a, between the first frame 106a and the second frame 106b, or outside of the second frame 106b. The first frame 106a may be arranged approximately along a perimeter of the flip chip die 104 or around the flip chip die 104 and the passive components 108. The second frame 106b may be arranged approximately along a perimeter of the substrate 102.

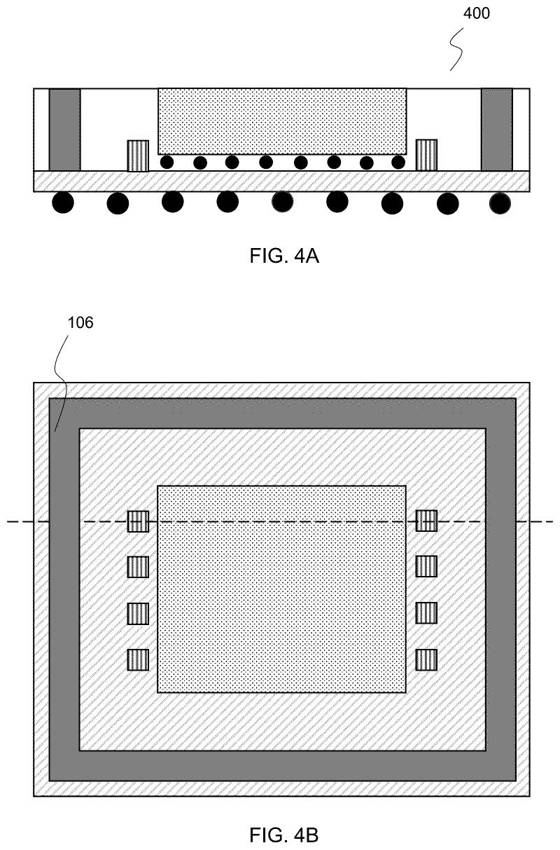

FIGS. 4A and 4B are diagrams showing a cross-sectional view (with mold) and a top view (without mold) of a large body FCCSP 400 according to various non-limiting aspects of the present disclosure. FIGS. 4A and 4B show a large body FCCSP 400 similar to the large body FCCSP 100 of FIGS. 1A and 1B except the height of the stiffener element 106 may be substantially the same as the height of the mounted flip chip die 104 on the substrate 102.

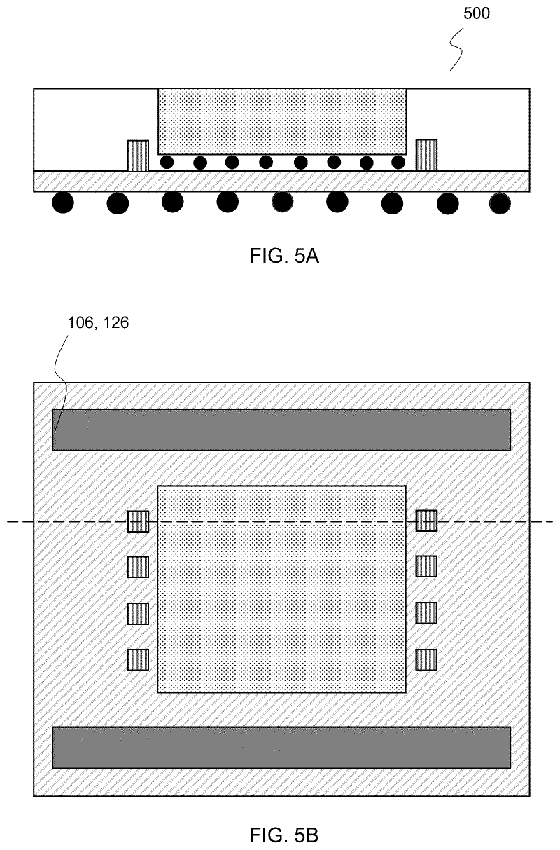

FIGS. 5A and 5B are diagrams showing a cross-sectional view (with mold) and a top view (without mold) of a large body FCCSP 500 according to various non-limiting aspects of the present disclosure. FIGS. 5A and 5B show a large body FCCSP 500 where the stiffener element 106 are two stability bars 126 extending along opposing sides of the flip chip die 104 in a direction parallel to a longer side of the substrate 102. The cross-section of the stability bars 126 has a planar or flat bottom for adhesion to the substrate. For example, the cross-section may be square, rectangular, trapezoidal or triangular. Each of the stability bars 126 are coupled (e.g., attached) to the substrate by adhesive.

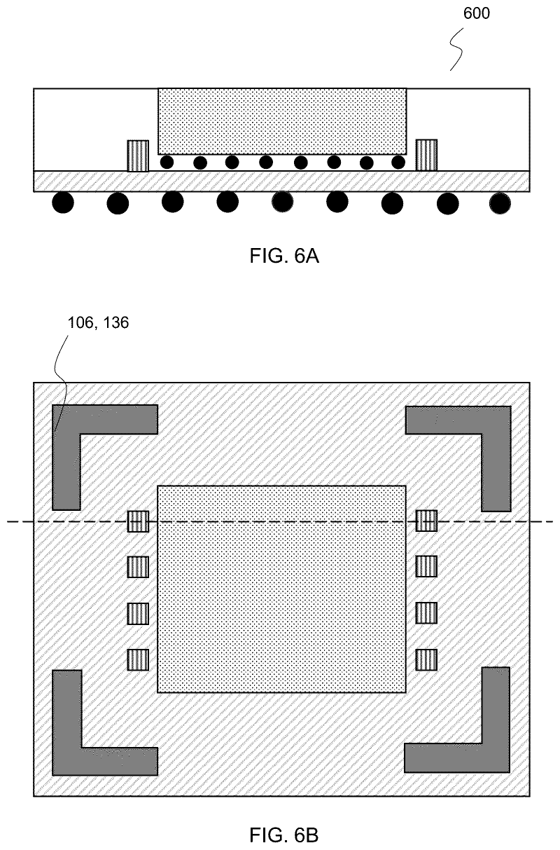

FIGS. 6A and 6B are diagrams showing a cross-sectional view (with mold) and a top view (without mold) of a large body FCCSP 600 according to various non-limiting aspects of the present disclosure. FIGS. 6A and 6B show a large body FCCSP 600 where the stiffener element 106 includes four L-shaped brackets 136, each arranged at a corner of the flip chip die 104. The cross-section of the L-shaped brackets has a planar or flat bottom for adhesion to the substrate. For example, the cross-section may be square, rectangular, trapezoidal or triangular. Each of the L-shaped brackets 136 are coupled (e.g., attached) to the substrate by adhesive.

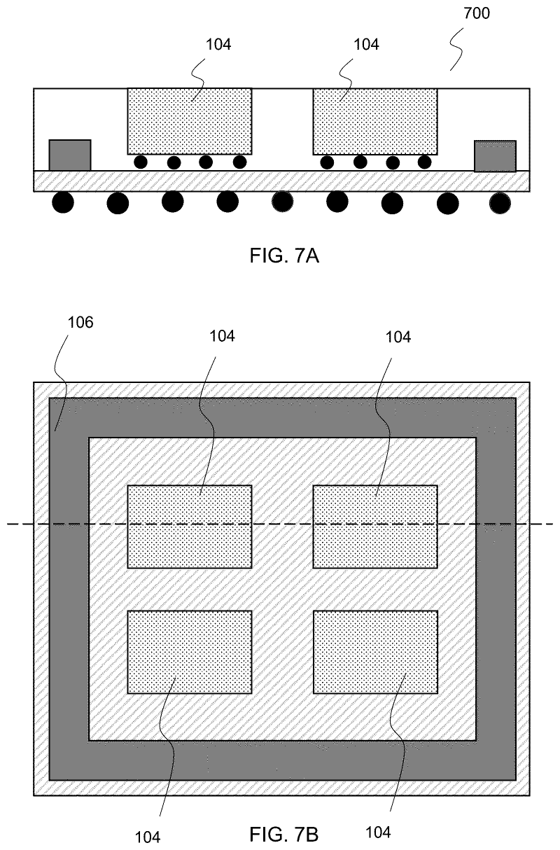

FIGS. 7A and 7B are diagrams showing a cross-sectional view (with mold) and a top view (without mold) of a large body FCCSP 700 according to various non-limiting aspects of the present disclosure. FIGS. 7A and 7B show a large body FCCSP 700 where the stiffener element 106 is a frame (e.g., rectangular or other shape) surrounding a plurality of flip chip dies 104. Each of the flip chip dies 104 are mounted to the substrate by solder bumps. The frame is coupled (e.g., attached) to the substrate by adhesive along the perimeter of the substrate 102.

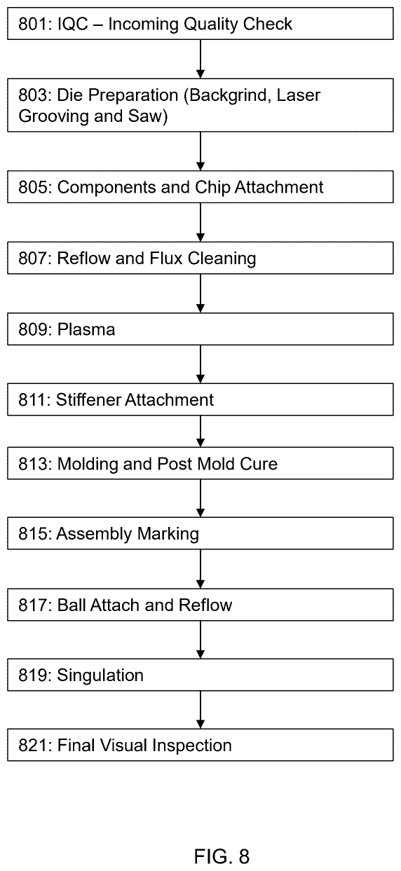

The stiffener addition may be an added step to the standard FCCSP assembly process flow. FIG. 8 illustrates a block diagram of the standard FCCSSP assembly process flow including the reinforcement or stiffener addition.

The standard FCCSP assembly process flow may include 801-809 and 813-821 of the following process flow:
At 801: IQC—Incoming Quality Check
At 803: Die Preparation (e.g., backgrind, laser grooving, saw)
At 805: Components and Chip Attachment
At 807: Reflow and Flux Cleaning
At 809: Plasma
At 811: Reinforcement or Stiffener Attachment
At 813: Molding and Post Mold Cure
At 815: Assembly Marking
At 817: Ball Attach and Reflow
At 819: Singulation
At 821: Final Visual Inspection

For example, at 805 one or more flip chip dies 104 may be coupled (e.g., attached) onto the top surface of substrate 102 according to the standard FCCSP process flow (e.g., solder bumps). At 805 any passive components 108 may also be coupled (e.g., attached) to the top surface of substrate 102 according to the standard FCCSP process flow (e.g., solder bumps).

For example, at 811 between 809: Plasma (i.e., pre-molding step) and 813: Molding and Post Mold Cure, the stiffener element 106 may be one or more prefabricated pieces that are coupled (e.g., attached) to the top surface of the substrate 102 with adhesive. The adhesive may for example be an epoxy-based or silicon-based adhesive.

After the stiffener element 106 is coupled (e.g., adhered) to the substrate, a mold is applied to encapsulate the stiffener element 106, one or more flip chip dies 104 and any passive components 108 on the substrate 102. The mold may be applied according to the standard FCCSP process flow. A polymer compound of the standard FCCSP process flow may be used.

Currently, FCCSP technology is limited to a body size of 2 mm×2 mm to 20 mm×20 mm. Beyond these dimensions, packaging uses FCBGA platform technology is needed due to very high warpage in the package. The addition of a stiffener element extends the FCCSP platform capability. Flip chip dies currently packaged in small form factor FCBGA packages may transition into the FCCSP space.

Large body FCCSP can prove advantageous because: (1) FCCSP throughput time is higher. FCBGA is a singulated package, whereas FCCSP is processed in a strip form; (2) FCCSP offers thin core (e.g., <200 um core) and coreless solutions; smaller line/space; reduced substrate layer counts; more options in materials. This can improve current carrying density; and (3) FCCSP is a low cost packaging platform compared to the FCBGA packaging platform from both a substrate and assembly process standpoint. This can be a huge cost saving.

### Metal Wire Mesh for Mold Compound Thermal Dissipation Enhancement

Better thermal dissipation is increasingly important with growing IC functionality needs. An industry standard high thermal mold compound offers about ˜3 W/mK of heat dissipation. Thus, current packaging platforms using the industry standard high thermal mold compound materials would only offer about ˜3 W/mK of heat dissipation.

The present disclosure provides a 5-fold improvement in heat dissipation without altering the mold compound chemistry and compounding.

The present disclosure provides an encapsulated reinforcement structure (e.g., wire mesh cage) arranged over one or more dies (e.g., flip chip dies) and coupled (e.g., attached) to the substrate. The reinforcement structure (e.g., wire mesh cage) may be coupled (.e.g., attached) at a pre-molding step and encapsulated with mold during the molding process. The encapsulated reinforcement structure (e.g., wire mesh cage) acts as heat dissipation channels within the mold. There is no localized hot spot because heat may be dissipated over the entire surface. This can improve heat transfer through the mold by five-fold.

The encapsulated reinforcement structure (e.g., wire mesh cage) may include a horizontal portion (e.g., cage ceiling) supported by vertical portions (e.g., cage side walls). In non-limiting embodiments, there may be four vertical portions forming a cuboid or cube-like cage enclosure.

The horizontal portion extends in a plane over the one or more dies. The horizontal portion can be directly over the one or more dies (e.g., silicon/chip/die) or above the one or more dies with some space in between. The horizontal portion includes a wire mesh having a fine pitch (e.g., a few microns), yet allows a polymer applied during a molding process to pass through the wire mesh and encapsulate the wire mesh within the polymer when the polymer sets. The mesh pattern should allow mold compound to flow through during the molding process. This acts as a reinforcement within the mold compound and also acts as a thermal heat transfer links. The figures illustrate a square mesh but this can be varied as triangular mesh; pentagon mesh etc depending on product and package requirement, coefficient of thermal expansion (CTE) mismatch, warpage, mold flowability and other aspects of the package integrity.

The vertical portions extend from the substrate to the horizontal portion and are arranged around the die or the collection of one or more dies. The vertical portions may be a solid wall or a wire mesh wall having a fine pitch (e.g., a few microns). The vertical portions include a base forming feet on top of the substrate for coupling (e.g., attaching) to the substrate. The feet are solid for stable contact on the substrate. The typical attachment interface is epoxy, adhesive materials, thermal paste, prepregs etc. For example, in non-limiting embodiments, the reinforcement structure (e.g., wire mesh cage) may be coupled (e.g., attached) using adhesive between the feet and the substrate.

The thicknesses of the sides and top are dependent on package and product requirements and coefficient of thermal expansion (CTE) mismatch between materials used in the overall package.

The reinforcement structure (e.g., wire mesh cage) may be a prefabricated piece manufactured with conventional procedures. The reinforcement structure may be fabricated from a wide range of metals or metal alloys, including e.g., stainless steel, copper, silver, gold, aluminum, nickel, chromium, etc. or alloys thereof.

The addition of a thermally conductive reinforcement structure (e.g., a fine metal wire mesh) in the mold does not require a special polymer (e.g., no changes to the polymer compound) and does not alter the polymer chemistry. That is, presently available polymer compounds may be used.

The metal mesh reinforcement structure may act as a straightforward thermal enhancement solution for a standard non-high thermal mold compound. The encapsulated metal mesh reinforcement structure can provide 5 times better thermal dissipation through the mold than through the mold alone without the metal mesh reinforcement structure.

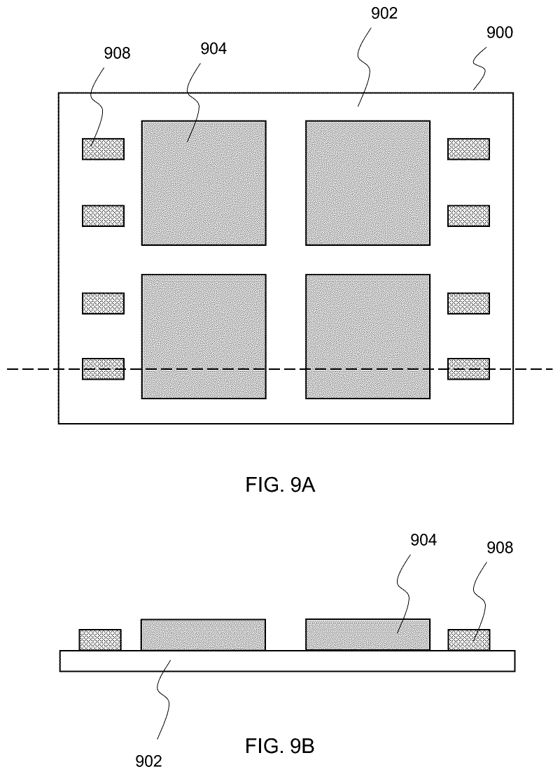

FIGS. 9A and 9B are diagrams showing a top view and a cross-sectional view of a chip module 900 prior to attachment of a reinforcement structure according to various non-limiting aspects of the present disclosure. FIGS. 9A and 9B show one or more flip chip dies 904 coupled (e.g., bonded) to a substrate 902. The one or more chips dies are arranged at a central portion of the substrate 902. One or more passive components 908 may also be coupled (e.g., attached) to the substrate 902.

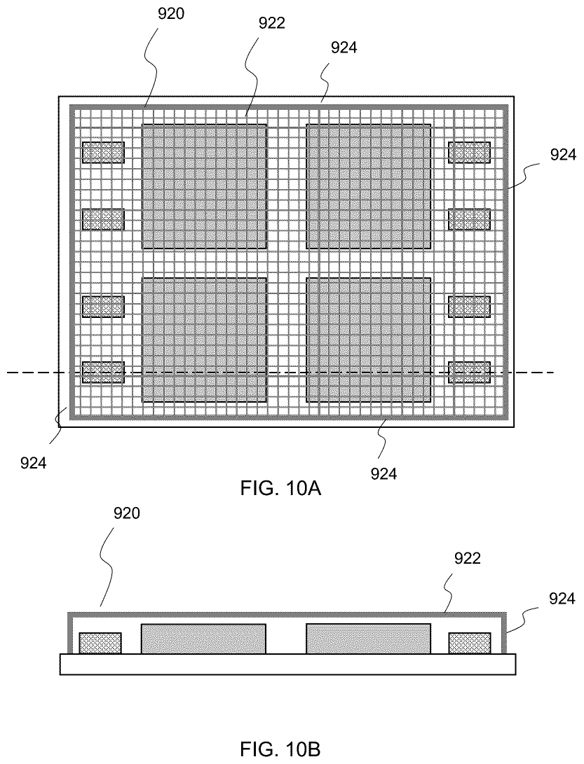

FIGS. 10A and 10B are diagrams showing a top view and a cross-sectional view of a chip module 900 after attachment of a reinforcement structure according to various non-limiting aspects of the present disclosure. FIGS. 10A and 10B show a reinforcement structure 920 covering one or more flip chip dies 904 coupled (e.g., bonded) to a substrate 902. The reinforcement structure 920 may be a metal wire mesh cage having a top wall 922 supported by four side walls 924. The base of the side walls 924 include planar or flat portions forming solid feet configured to be coupled (e.g., attached) to a top surface of the substrate 902. For example, the planar portions continuously contact the substrate via the adhesive. The reinforcement structure 920 may be a cube-shaped dome. An epoxy-based or silicon-based adhesive may be used to couple (e.g., attach) the reinforcement structure 920 to the substrate. Alternatively, other adhesive materials such as thermal paste, prepregs etc. may be used. As shown in FIG. 10B, there may be space between the top surface of the one or more flip chip dies 904 and the top wall 922 of the reinforcement structure 920. In some non-limiting embodiments, the top wall 922 may be directly on the one or more flip chip dies 904. FIG. 10A shows a metal mesh pattern having a square shape, but the metal mesh pattern may be of any shape. The mesh pattern should have a fine pitch (e.g., a few microns).

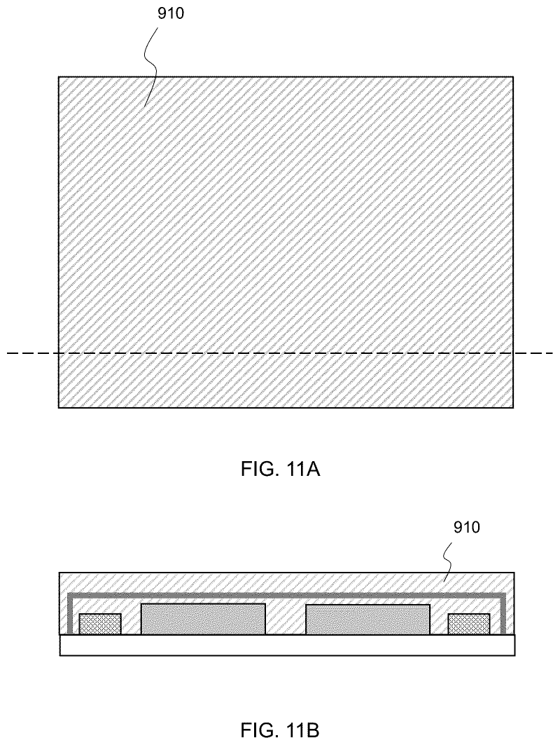

FIGS. 11A and 11B are diagrams showing a top view and a cross-sectional view of a chip module 900 after encapsulating a reinforcement structure in a mold according to various non-limiting aspects of the present disclosure. FIGS. 11A and 11B show a reinforcement structure 920 embedded in polymer forming mold 910.

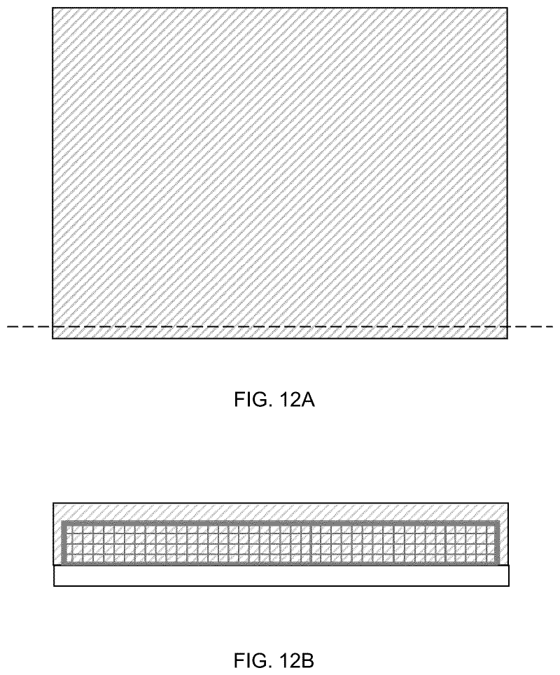

FIGS. 12A and 12B are diagrams showing a top view and a cross-sectional view of a chip module 900 after encapsulating a reinforcement structure in a mold according to various non-limiting aspects of the present disclosure. FIGS. 12A and 12B show a cross-section of reinforcement structure 920 at one of the side walls 924. FIG. 12B shows a side wall that is a mesh wall. The side wall 924 may have the same mesh pattern as the top wall 922. In some non-limiting embodiments, the side wall 924 may have a different mesh pattern than the top wall 922. In other non-limiting embodiments, the side wall may be a solid wall. FIG. 12B also shows that the base of the side wall 924 is planar or flat.

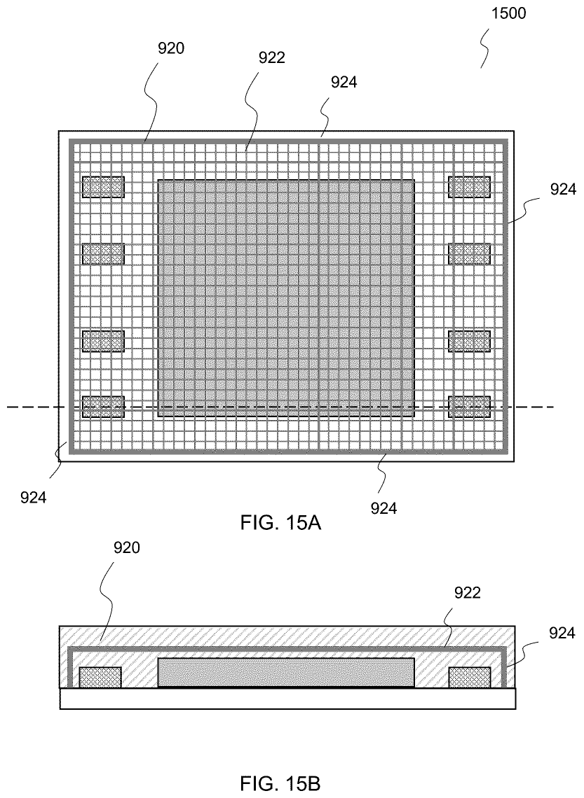

FIGS. 15A and 15B are diagrams showing a top view (without mold) and a cross-sectional view (with mold) of a chip module 1500 according to various non-limiting aspects of the present disclosure. FIGS. 15A and 15B show a reinforcement structure 920 embedded in polymer forming mold 910 and covering one flip chip die 904.

The metal mesh may be physically coupled (e.g., attached) to the substrate.

The present disclosure offers a 5-fold improvement in heat dissipation through the mold compound. The present disclosure provides an easy external fix without having to alter mold compound polymer chemistry for molded packages.

The thermal dissipation component may be a reinforcement structure (e.g., mesh cage) that is arranged within the molded area. For example, the thermal dissipation component may be a fine metal wire mesh attachment. The fine metal wire mesh may be coupled (e.g., attached) at a pre-molding step and encapsulated with a molding polymer during molding process. The fine metal wire mesh acts as heat dissipation channels within the mold. This can improve heat transfer through the mold by about 5 times or even more the heat transfer of the mold.

The material, thickness and foot width of the fine wire mesh can be defined and varied per individual product package requirement. The wire mesh may have a pitch of a few microns.

In some non-limiting embodiments, an additional heat sink may be added on a top surface of the mold.

The reinforcement structure 920 (e.g., metal wire mesh cage) addition may be an added step to the standard laminate assembly process flow. The reinforcement structure 920 (e.g., metal wire mesh cage) may be added to FCBGA packaging or FCCSP packaging.

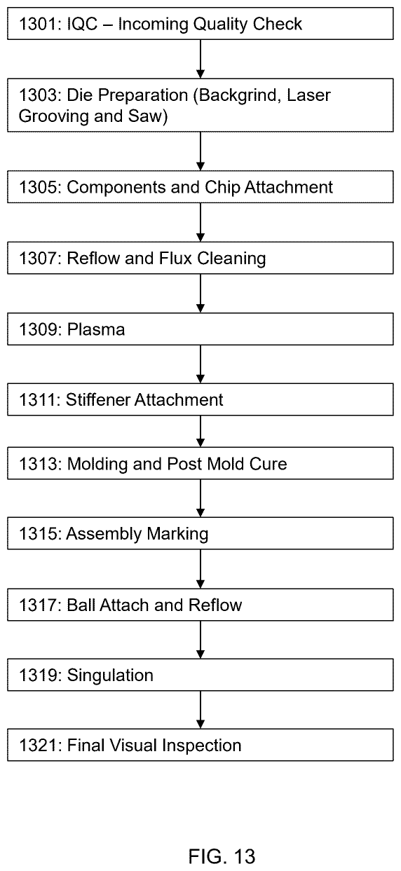

The reinforcement addition may be an added step to the standard FCCSP assembly process flow. FIG. 13 illustrates a block diagram of the standard FCCSP assembly process flow including the reinforcement addition.

The standard FCCSP assembly process flow may include 1301-1309 and 1313-1321 of the following process flow:
At 1301: IQC—Incoming Quality Check
At 1303: Die Preparation (e.g., backgrind, laser grooving, saw)
At 1305: Components and Chip Attachment
At 1307: Reflow and Flux Cleaning
At 1309: Plasma
At 1311: Reinforcement Attachment
At 1313: Molding and Post Mold Cure
At 1315: Assembly Marking
At 1317: Ball Attach and Reflow
At 1319: Singulation
At 1321: Final Visual Inspection

For example, at 1305 one or more flip chip dies 904 may be coupled (e.g., attached) onto the top surface of substrate 902 according to the standard FCCSP process flow (e.g., solder bumps). At 1305 any passive components 908 may also be coupled (e.g., attached) onto the top surface of substrate 102 according to the standard FCCSP process flow (e.g., solder bumps).

At 1311 between 1309: Plasma (i.e., pre-molding step) and 1313: Molding and Post Mold Cure, the reinforcement structure 920 may be a prefabricated piece that is coupled (e.g., attached) to the top surface of the substrate with adhesive. The prefabricated piece may be a metal wire mesh cage. The base or feet of the cage may be coupled (e.g., attached) to the substrate with adhesive. The adhesive may for example be an epoxy-based or silicon-based adhesive.

At 1313, after the reinforcement structure 920 is coupled (e.g., adhered) to the substrate, a mold is applied to encapsulate the reinforcement structure 920, one or more flip chip dies 904 and any passive components 908 on the substrate 902. The mold may be applied according to the standard FCCSP process flow. A polymer compound of the standard FCCSP process flow may be used.

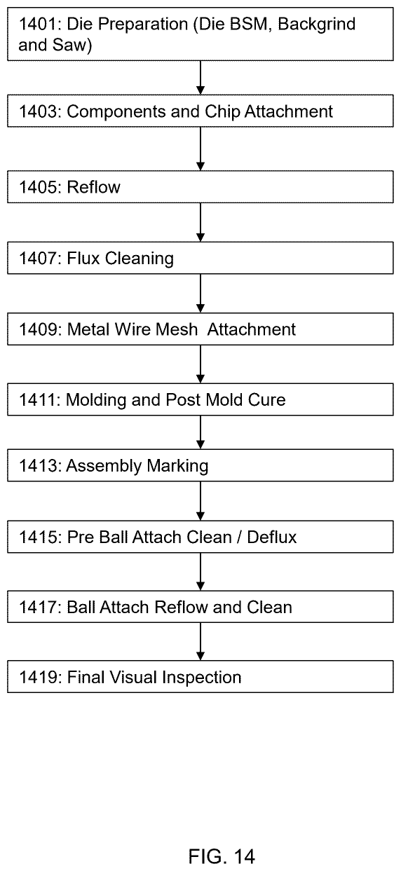

The reinforcement addition may be an added step to the standard FCBGA assembly process flow. FIG. 14 illustrates a block diagram of the standard FCBGA assembly process flow including the reinforcement addition.

The standard FCBGA assembly process flow may include 1401-1409 and 1413-1421 of the following process flow:
At 1401: Die Preparation (e.g., Die BSM, backgrind, saw)
At 1403: Components and Chip Attach
At 1405: Reflow
At 1407: Flux Cleaning
At 1409: Metal Wire Mesh Attach
At 1411: Molding and Post Mold Cure
At 1413: Assembly Marking
At 1415: Pre Ball Attach Clean/Deflux
At 1417: Ball Attach
At 1419: Final Visual Inspection

For example, at 1403 one or more flip chip dies 904 may be coupled (e.g., attached) to the top surface of substrate 902 according to the standard FCBGA process flow (e.g., solder bumps). At 1403 any passive components 908 may also be coupled (e.g., attached) to the top surface of substrate 102 according to the standard FCBGA process flow (e.g., solder bumps).

At 1409 between 1407: Flux Cleaning (i.e., pre-molding step) and 1311: Molding and Post Mold Cure, the reinforcement structure 920 may be a prefabricated piece that is coupled (e.g., attached) to the top surface of the substrate with adhesive. The prefabricated piece may be a metal wire mesh cage. The base or feet of the cage may be coupled (e.g., attached) to the substrate with adhesive. The adhesive may for example be an epoxy-based or silicon-based adhesive.

At 1411, after the reinforcement structure 920 is coupled (e.g., adhered) to the substrate, a mold is applied to encapsulate the reinforcement structure 920, one or more flip

chip dies 904 and any passive components 908 on the substrate 902. The mold may be applied according to the standard FCBGS process flow. A polymer compound of the standard FCBGA process flow may be used.

The present disclosure provides several advantages.

A fine metal wire mesh is simple to fabricate and easy to implement using conventional manufacturing methods. It can provide 5 times better thermal dissipation through the mold.

A fine metal wire mesh does not require a special polymer compounding change and does not alter the polymer chemistry.

A fine metal wire mesh can be made with wide range of metal of choice.

A fine metal wire mesh is a straightforward thermal enhancement solution for a standard non-high thermal mold compound.

While this specification contains many details, these should not be understood as limitations on the scope of what may be claimed, but rather as descriptions of features specific to particular examples. Certain features that are described in this specification or shown in the drawings in the context of separate aspects can also be combined. Conversely, various features that are described or shown in the context of a single aspect can also be implemented in multiple aspects separately or in any suitable sub-combination.

Similarly, while steps/operations of the methods as described above are depicted in a particular order (e.g. as shown in the drawings), this should not be understood as requiring that such operations/steps be performed in the particular order shown or in sequential order, or that all illustrated operations be performed, to achieve desirable results. In certain circumstances, multitasking and parallel processing may be advantageous. For example, some operations/steps may occur in different orders and/or concurrently with other operations/steps apart from those illustrated and/or described herein. In addition, not all illustrated operations/steps may be required to implement one or more aspects or aspects described herein. Also, one or more of the steps depicted herein may be carried out in one or more separate acts and/or phases.

Moreover, the separation/integration of various system components in the aspects described above should not be understood as requiring such separation/integration in all aspects, and it should be understood that the described program components and systems can generally be integrated together in a single product or separated into multiple products.

A number of aspects have been described. Nevertheless, it will be understood that various modifications can be made. Accordingly, other aspects are within the scope of the following claims.

Example 1 may be a device comprising: a substrate; at least one chip die coupled to a top surface of the substrate at a central portion of the substrate; a reinforcement structure disposed around the at least one chip die, a bottom surface of the reinforcement structure coupled to the top surface of the substrate; and a mold structure surrounding the reinforcement structure and the at least one chip die.

Example 2 may include the device of Example 1 or some other example herein, wherein the reinforcement structure includes a metal, metal alloy, plastic, ceramic, or polymer structure.

Example 3 may include the device of Example 1 or 2, wherein the reinforcement structure is a frame surrounding the at least one chip die.

Example 4 may include the device of any one of Examples 1-3, wherein the reinforcement structure is spaced apart from side edges of the substrate.

Example 5 may include the device of any one of Examples 1-4, wherein the reinforcement structure is spaced apart from side edges of the at least one chip die.

Example 6 may include the device of any one of Examples 1-5, wherein a height of the reinforcement structure is less than a height of the at least one chip die.

Example 7 may include the device of any one of Examples 1-6, wherein the bottom surface of the reinforcement structure is disposed along side edges of the substrate.

Example 8 may include the device of any one of Examples 1-7, wherein the bottom surface of the reinforcement structure is disposed along side edges of the at least one chip die.

Example 9 may include the device of any one of Examples 1-8, wherein the reinforcement structure comprises a first frame surrounding the at least one chip die and a second frame surrounding the first frame and the at least one chip die.

Example 10 may include the device of any one of Examples 1-8, wherein the reinforcement structure comprises two stability bars arranged on opposing sides of the at least one chip die and oriented parallel to a longer side of the substrate.

Example 11 may include the device of any one of Examples 1-8, wherein the reinforcement structure comprises four L-shaped brackets arranged at respective corners of the at least one chip die.

Example 12 may include the device of any one of Examples 1-11, further comprising a passive component coupled to the substrate.

Example 13 may include the device of Example 1, wherein the reinforcement structure comprises a top wall supported by side walls, the top wall of the reinforcement structure thermally coupled to the at least one chip die, bases of the side walls coupled to the top surface of the substrate along edges of the substrate, wherein the top wall comprises a mesh pattern.

Example 14. The device of Example 13, wherein the side walls comprise a mesh pattern.

Example 15 may include the device of Example 13 or 14, wherein the reinforcement structure is comprised of metal.

Example 16 may include the device of any one of Examples 13-15, wherein the perimeter of the reinforcement structure is rectangular shaped.

Example 17 may include the device of any one of Examples 13-16, wherein the reinforcement structure has a cuboid shape.

Example 18 may include the device of any one of Examples 13-17, wherein the mesh pattern has a fine pitch.

Example 19 may include the device of any one of Examples 13-18, wherein the bases of the side walls comprise flat feet.

Example 20 may include the device of any one of Examples 13-19, wherein the reinforcement structure is completely embedded in the mold structure.

Example 21 may include the device of any one of Examples 13-20, wherein the top wall directly contacts the at least one chip die.

Example 22. A method comprising: providing a substrate; providing at least one chip die coupled to a top surface of the substrate at a central portion of the substrate; providing a reinforcement structure disposed around the at least one chip die, a bottom surface of the reinforcement structure coupled to the top surface of the substrate; and providing a mold structure surrounding the reinforcement structure and the at least one chip die.

Example 23 may include the method of Example 22, wherein the reinforcement structure includes a metal, metal alloy, plastic, ceramic, or polymer structure.

Example 24 may include the method of Example 22 or 23, wherein the reinforcement structure is a frame surrounding the at least one chip die.

Example 25 may include the method of any one of Examples 22-24, wherein the reinforcement structure is spaced apart from side edges of the substrate.

Example 26 may include the method of any one of Examples 22-25, wherein the reinforcement structure is spaced apart from side edges of the at least one chip die.

Example 27 may include the method of any one of Examples 22-26, wherein a height of the reinforcement structure is less than a height of the at least one chip die.

Example 28 may include the method of any one of Examples 22-27, wherein the bottom surface of the reinforcement structure is disposed along side edges of the substrate.

Example 29 may include the method of any one of Examples 22-28, wherein the bottom surface of the reinforcement structure is disposed along side edges of the at least one chip die.

Example 30 may include the method of any one of Examples 22-29, wherein the reinforcement structure comprises a first frame surrounding the at least one chip die and a second frame surrounding the first frame and the at least one chip die.

Example 31 may include the method of any one of Examples 22-29, wherein the reinforcement structure comprises two stability bars arranged on opposing sides of the at least one chip die and oriented parallel to a longer side of the substrate.

Example 32 may include the method of any one of Examples 22-29, wherein the reinforcement structure comprises four L-shaped brackets arranged at respective corners of the at least one chip die.

Example 33 may include the method of any one of Examples 22-32, further comprising a passive component coupled to the substrate.

Example 34 may include the method of Example 22, wherein the reinforcement structure comprises a top wall supported by side walls, the top wall of the reinforcement structure thermally coupled to the at least one chip die, bases of the side walls coupled to the top surface of the substrate along edges of the substrate, wherein the top wall comprises a mesh pattern.

Example 35 may include the method of Example 34, wherein the side walls comprise a mesh pattern.

Example 36 may include the method of Example 34 or 35, wherein the reinforcement structure is comprised of metal.

Example 37 may include the method of any one of Examples 34-36, wherein the perimeter of the reinforcement structure is rectangular shaped.

Example 38 may include the method of any one of Examples 34-37, wherein the reinforcement structure has a cuboid shape.

Example 39 may include the method of any one of Examples 34-38, wherein the mesh pattern has a fine pitch.

Example 40 may include the method of any one of Examples 34-39, wherein the bases of the side walls comprise flat feet.

Example 41 may include the method of any one of Examples 34-40, wherein the reinforcement structure is completely embedded in the mold structure.

Example 42 may include the method of any one of Examples 34-41, wherein the top wall directly contacts the at least one chip die.

What is claimed is:

1. A device comprising:
a substrate;
at least one chip die coupled to a top surface of the substrate at a central portion of the substrate;
a reinforcement structure disposed around the at least one chip die, a bottom surface of the reinforcement structure coupled to the top surface of the substrate; and
a mold structure surrounding the reinforcement structure and the at least one chip die.

2. The device of claim 1, wherein the reinforcement structure includes a metal, metal alloy, plastic, ceramic, or polymer structure.

3. The device of claim 1, wherein the reinforcement structure is a frame surrounding the at least one chip die.

4. The device of claim 1, wherein the reinforcement structure is spaced apart from side edges of the substrate.

5. The device of claim 1, wherein the reinforcement structure is spaced apart from side edges of the at least one chip die.

6. The device of claim 1, wherein the reinforcement structure comprises a top wall supported by side walls, the top wall of the reinforcement structure thermally coupled to a top surface of the at least one chip die, bases of the side walls coupled to the top surface of the substrate along edges of the substrate,
wherein the top wall comprises a mesh pattern.

7. The device of claim 6, wherein the side walls comprise a mesh pattern and wherein the bases of the side walls comprise flat feet.

8. The device of claim 6, wherein the reinforcement structure is comprised of metal.

9. The device of claim 6, wherein the reinforcement structure has a cuboid shape.

10. The device of claim 6, wherein the reinforcement structure is embedded in the mold structure.

11. A method comprising:
providing a substrate;
providing at least one chip die coupled to a top surface of the substrate at a central portion of the substrate;
providing a reinforcement structure disposed around the at least one chip die, a bottom surface of the reinforcement structure coupled to the top surface of the substrate; and
providing a mold structure surrounding the reinforcement structure and the at least one chip die.

12. The method of claim 11, wherein the reinforcement structure includes a metal, metal alloy, plastic, ceramic, or polymer structure.

13. The method of claim 11, wherein the reinforcement structure is a frame surrounding the at least one chip die.

14. The method of claim 11, wherein the reinforcement structure is spaced apart from side edges of the substrate.

15. The method of claim 11, wherein the reinforcement structure is spaced apart from side edges of the at least one chip die.

16. The method of claim 11, wherein the reinforcement structure comprises a top wall supported by side walls, the top wall of the reinforcement structure thermally coupled to a top surface of the at least one chip die, bases of the side walls coupled to the top surface of the substrate along edges of the substrate,
wherein the top wall comprises a mesh pattern.

17. The method of claim 16, wherein the side walls comprise a mesh pattern and wherein the bases of the side walls comprise flat feet.

18. The method of claim 16, wherein the reinforcement structure is comprised of metal.

19. The method of claim 16, wherein the reinforcement structure has a cuboid shape.

20. The method of claim 16, wherein the reinforcement structure is embedded in the mold structure.
